(19) United States
(12) Patent Application Publication
(10) Pub. No.: US 2024/0071925 A1
(43) Pub. Date: Feb. 29, 2024

(54) FET SUBSTRATE TRIMMING WITH IMPROVED VIA PLACEMENT

(71) Applicant: INTERNATIONAL BUSINESS MACHINES CORPORATION, Armonk, NY (US)

(72) Inventors: Liqiao Qin, Albany, NY (US); Tao Li, Slingerlands, NY (US); Ruilong Xie, Niskayuna, NY (US); Chen Zhang, Guilderland, NY (US); Kisik Choi, Watervliet, NY (US)

(21) Appl. No.: 17/898,765

(22) Filed: Aug. 30, 2022

(51) Int. Cl. H01L 23/528; H01L 21/8234; H01L 23/522; H01L 27/088; H01L 29/40; H01L 29/417; H01L 29/66

(52) U.S. Cl. CPC H01L 23/5286; H01L 21/823418; H01L 21/823475; H01L 23/5226; H01L 23/5283; H01L 27/088; H01L 29/401; H01L 29/41733; H01L 29/41775; H01L 29/66545; H01L 29/42392

(57) ABSTRACT

Semiconductor devices and methods of forming the same include a semiconductor base having a first width. A semiconductor device over the semiconductor base has a second width that is greater than the first width. A power rail is beneath the semiconductor base. A conductive contact extends from a top of the semiconductor device to the power rail.

### BACKGROUND

The present invention generally relates to semiconductor device fabrication, and, more particularly, to forming contacts to buried power rails in integrated chips.

Buried power rails can help to simplify integrated chip design by placing power-carrying lines underneath a device, leaving room for signal-carrying lines over the devices.

### SUMMARY

A semiconductor device includes a semiconductor base having a first width. A semiconductor device is over the semiconductor base, having a second width that is greater than the first width. A power rail is beneath the semiconductor base. A conductive contact extends from a top of the semiconductor device to the power rail.

A semiconductor device includes a pair of adjacent semiconductor bases, each having a first width. A pair of adjacent semiconductor devices are each positioned over a respective base of the pair of adjacent semiconductor bases and each have a second width that is greater than the first width. The pair of adjacent semiconductor devices each have a sidewall that is vertically aligned with a sidewall of the respective base. A power rail is beneath the pair of adject semiconductor bases. A conductive contact that extends from a top of one of the pair of adjacent semiconductor devices to the power rail.

A method of forming a semiconductor device includes etching a stack of alternating semiconductor layers over a semiconductor base. A protective layer is formed on a sidewall of the stack. A sidewall of the semiconductor base is etched back to reduce a width of the semiconductor base relative to a width of the stack. A device is formed from the stack. A contact is formed that penetrates from above the device to below the semiconductor base.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a step in the fabrication of a semiconductor device, establishing cross-sections AA, BB, and CC, in accordance with an embodiment of the present invention;

FIG. 2 is a cross-sectional view of a step in the fabrication of a semiconductor device, showing the formation of alternating semiconductor layers over a base substrate, in accordance with an embodiment of the present invention;

FIG. 3 is a cross-sectional view of a step in the fabrication of a semiconductor device, showing the formation of stacks of alternating semiconductor layers in respective device regions, in accordance with an embodiment of the present invention;

FIG. 4 is a cross-sectional view of a step in the fabrication of a semiconductor device, showing the formation of a protective layer on sidewalls of the stacks of alternating semiconductor layers, in accordance with an embodiment of the present invention;

FIG. 5 is a cross-sectional view of a step in the fabrication of a semiconductor device, showing an etch that thins the base substrates, in accordance with an embodiment of the present invention;

FIG. 6 is a cross-sectional view of a step in the fabrication of a semiconductor device, showing the removal of the protective layer and formation of a dielectric around the base substrates, in accordance with an embodiment of the present invention;

FIG. 7 is a set of cross-sectional views of a step in the fabrication of a semiconductor device, showing the formation of dummy gates, in accordance with an embodiment of the present invention;

FIG. 8 is a set of cross-sectional views of a step in the fabrication of a semiconductor device, showing the formation of semiconductor devices with respective source/drain regions, in accordance with an embodiment of the present invention;

FIG. 9 is a set of cross-sectional views of a step in the fabrication of a semiconductor device, showing the formation of semiconductor devices with respective gate stacks, in accordance with an embodiment of the present invention;

FIG. 10 is a set of cross-sectional views of a step in the fabrication of a semiconductor device, showing the formation of a via that penetrates to a layer below the semiconductor devices, in accordance with an embodiment of the present invention;

FIG. 11 is a set of cross-sectional views of a step in the fabrication of a semiconductor device, showing the formation of an electrical contact in the via, in accordance with an embodiment of the present invention;

FIG. 12 is a set of cross-sectional views of a step in the fabrication of a semiconductor device, showing the removal of a substrate to expose a surface of the electrical contact, in accordance with an embodiment of the present invention;

FIG. 13 is a set of cross-sectional views of a step in the fabrication of a semiconductor device, showing the formation of a buried power rail in contact with the electrical contact, in accordance with an embodiment of the present invention;

FIG. 14 is a cross-sectional view of a step in the fabrication of a semiconductor device, showing the deposition of a dielectric material around a thinned base substrate, in accordance with an embodiment of the present invention;

FIG. 15 is a cross-sectional view of a step in the fabrication of a semiconductor device, showing the formation of dielectric spacers around the thinned base substrate, in accordance with an embodiment of the present invention;

FIG. 16 is a block/flow diagram of a method of fabricating a semiconductor device, in accordance with an embodiment of the present invention;

FIG. 17 is a cross-sectional view of a step in the fabrication of a semiconductor device, showing the formation of a protective layer on one sidewall of the stacks of alternating semiconductor layers, in accordance with an embodiment of the present invention;

FIG. 18 is a cross-sectional view of a step in the fabrication of a semiconductor device, showing an etch that thins the base substrates from one side, in accordance with an embodiment of the present invention;

FIG. 19 is a cross-sectional view of a step in the fabrication of a semiconductor device, showing the formation of a dielectric spacer at one side of the thinned base substrate, in accordance with an embodiment of the present invention; and

FIG. 20 is a block/flow diagram of a method of fabricating a semiconductor device, in accordance with an embodiment of the present invention.

### DETAILED DESCRIPTION

In transistor devices, such as field effect transistors (FETs), forming an electrical contact to a buried power rail may be accomplished using a via that pierces the interlayer dielectric. However, vias that provide contacts to an underlying power rail may complicate chip design, as they pose a risk of creating shorts to other structures. Keeping the via at a distance from the device decreases the areal density of an integrated chip, as devices would be spaced farther apart to make use of the buried power rail.

To improve the electrical insulation between the via and the substrate underneath a device, some of the substrate may be removed and may be replaced with an insulating dielectric structure. The via can then be positioned closer to the source/drain region of the device without a risk of shorting to the substrate. In particular, thinning the substrate makes it possible to position the via so that it touches the sidewalls of the source/drain region of the device, creating additional space between the via and neighboring devices.

In some cases, the substrate may be thinned on two sides. In other cases, the substrate may be etched on one side, with the other side remaining whole. In either case, one or more dielectric materials may be filled into the gap that is left by thinning the substrate. The resulting thinned substrate may have a width that is less than a width of the device's channel.

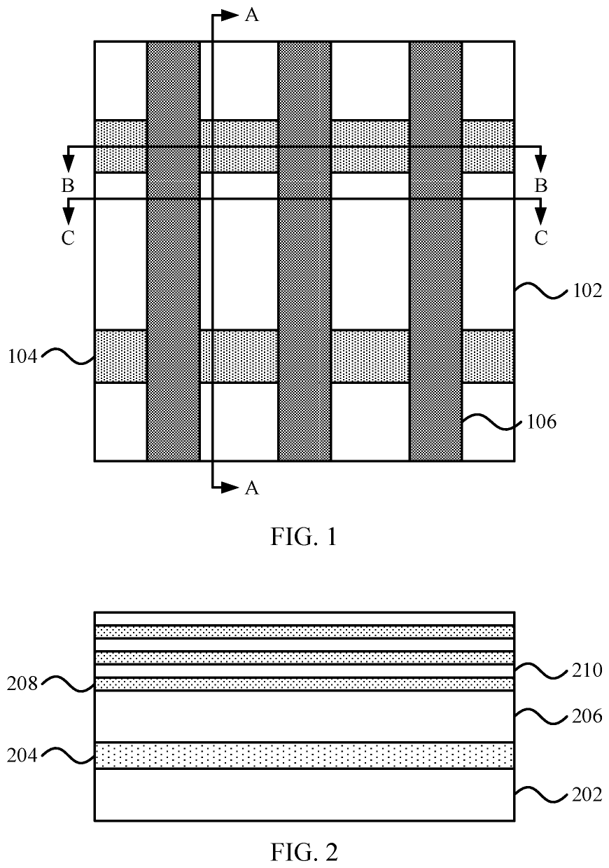

Referring now to FIG. 1, a top-down view of a step in the fabrication of an integrated chip is shown. A semiconductor substrate 102 is shown with stacks of semiconductor layers 104 on it and with dummy gate structures 106 formed across the stacks 104.

Three cross-sections are indicated, including AA, which cuts parallel to the dummy gates 106 in a region that will include source/drain regions of the transistor devices, BB, which cuts parallel to the stacks 104 and through the stacks 104 in a region that will include a channel region of the transistor devices, and CC, which cuts parallel to the stacks 104 but which cuts through a gate cut region between transistor devices.

Referring now to FIG. 2, a cross-sectional view of a step in the fabrication of a semiconductor device is shown along cross-section AA. A semiconductor device substrate 206 is positioned over a buried oxide layer 204, which in turn is positioned on a bulk semiconductor layer 202. A stack of alternating sacrificial layers 208 and channel layers 210 are formed over the device substrate 206.

The semiconductor device substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. The underlying bulk semiconductor layer 202 may be formed from a same semiconductor material as the semiconductor device substrate 206 or from a different material. The buried oxide layer 204 separating the semiconductor device substrate 206 from the bulk semiconductor layer 202 may be any appropriate dielectric material, such as silicon dioxide.

The alternating sacrificial layers 208 and channel layers 210 may be grown from the top surface of the semiconductor device substrate 206 by alternating epitaxial growth processes. As used herein, the terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

The sacrificial layers 208 and the channel layers 210 may be formed from semiconductor materials, such as silicon germanium and silicon, respectively, which are selectively etchable with respect to one another. As used herein, the term “selective” in reference to a material removal process denotes that the rate of material removal for a first material is greater than the rate of removal for at least another material of the structure to which the material removal process is being applied. For example, an etching process may remove silicon germanium from the sacrificial layers 208 faster than silicon is removed from the channel layers, with a rate of removal depending on a germanium concentration of the silicon germanium. Although silicon and silicon germanium are specifically contemplated, any appropriate materials may be used in their place.

The sacrificial semiconductor layers 208 and the channel layers 210 may have respective thicknesses that are lower than a critical thickness that depends on the composition of the layers. For example, although silicon germanium has a very similar crystal structure to silicon, and can be epitaxially grown from silicon, the atomic spacing in a silicon germanium crystal is slightly different from that of silicon. As a result, when a critical thickness of silicon germanium is exceeded in an epitaxial growth process, a defect may occur as the silicon germanium starts to assert its default spacing.

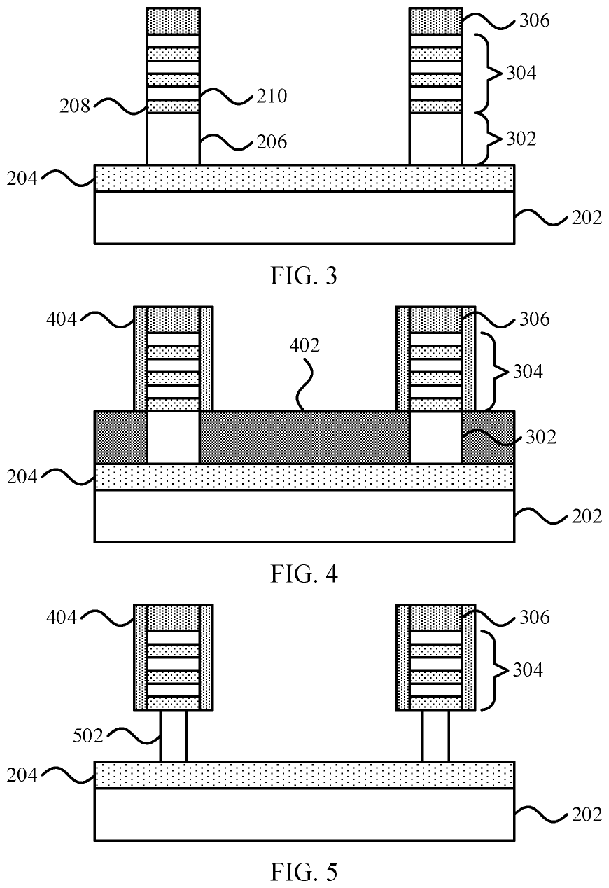

Referring now to FIG. 3, a cross-sectional view of a step in the fabrication of a semiconductor device is shown along cross-section AA. The semiconductor device substrate 206 and the alternating sacrificial layers 208 and channel layers 210 are patterned and etched to form base substrates 302 and stacks 304. Any appropriate patterning process may be used, such as a photolithographic process that creates a mask 306, followed by one or more anisotropic selective etches that stop on the buried oxide layer 204.

Reactive Ion Etching (RIE) is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation.

Referring now to FIG. 4, a cross-sectional view of a step in the fabrication of a semiconductor device is shown along cross-section AA. A sacrificial layer 402 is formed around the base substrates 302, for example using an organic planarizing layer, and is etched back to expose the stacks 304 using any appropriate isotropic or anisotropic etch. A protective layer 404 is formed on sidewalls of the stacks 304, for example by conformally depositing a dielectric material such as silicon nitride and then etching the dielectric material from horizontal surfaces using a selective anisotropic etch.

Referring now to FIG. 5, a cross-sectional view of a step in the fabrication of a semiconductor device is shown along cross-section AA. The sacrificial layer 402 is stripped away to expose sidewalls of the base substrates 302. A timed selective isotropic etch is used to remove material from the exposed sidewalls of the base substrates 302, while portions of the stacks 304 that are covered by the protective layer 404 are not harmed by the etch. The thinned base substrates 502 support the stacks 304, but may have a width that is less than a width of the stacks 304.

At this point, different embodiments may diverge to modify the base substrates 302 in different ways. The following figures will show a complete process for a first embodiment, and then alternative embodiments will be shown with the replaced steps being indicated.

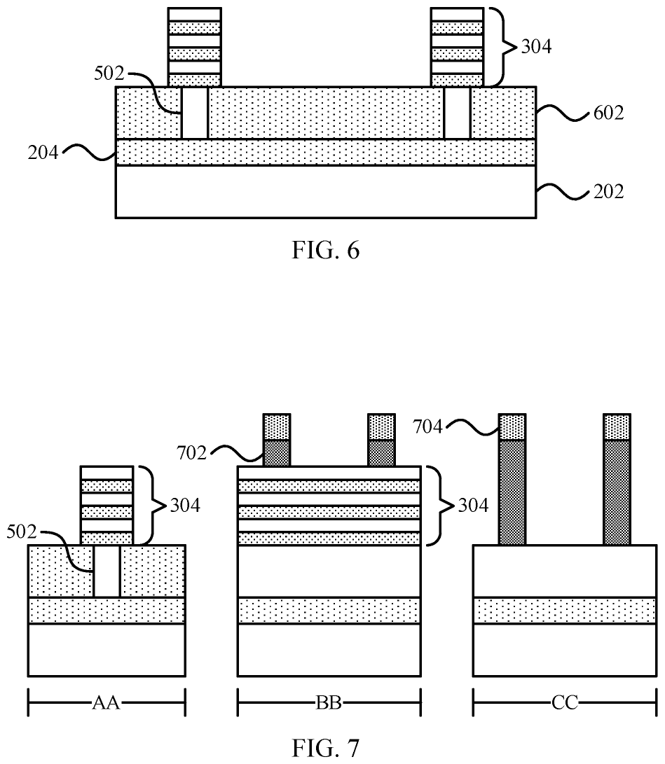

Referring now to FIG. 6, a cross-sectional view of a step in the fabrication of a semiconductor device is shown along cross-section AA. An isolation dielectric 602 is formed between the thinned base substrates 502, for example from silicon dioxide or any other appropriate dielectric material. The isolation dielectric 602 may be formed by any appropriate deposition process and may be etched back to the height of the thinned base substrates using any appropriate etching process. The masks 306 and the protective layers 404 are etched away as well, exposing the stacks 304.

Referring now to FIG. 7, a series of cross-sectional views of a step in the fabrication of a semiconductor device is shown, including cross-sections AA, BB, and CC. Dummy gates 702 are formed over the stacks 304. The dummy gates 702 may be formed by depositing a dummy gate material, such as polysilicon, forming a mask 704 using a photolithography process, and etching away exposed portions of the dummy gate material using an anisotropic etch.

The dummy gate material may be deposited using any appropriate process including, e.g., chemical vapor deposition (CVD), physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

Referring now to FIG. 8, a series of cross-sectional views of a step in the fabrication of a semiconductor device is shown, including cross-sections AA, BB, and CC. The dummy gates 702 are used as a pattern to etch down into the stacks 304, etching the sacrificial layers 208 and the channel layers 210.

Inner spacers 806 are formed at exposed ends of the sacrificial layers 208. This may be performed in some cases by etching back the sacrificial layers 208 relative to the channel layers 210 to create gaps, after which dielectric material may be deposited to fill the gaps. In other cases, the inner spacers 806 may be formed by an oxidizing condensation process, whereby silicon in the sacrificial layers 208 may form silicon dioxide, forcing germanium in the sacrificial layers 208 inward. In either case, excess dielectric material that extends past the etched channel layers 808 can be removed using a selective anisotropic etch, leaving inner spacers 806 and remnant sacrificial layers 810.

After formation of the inner spacers 806, source/drain regions 802 may be epitaxially grown from exposed side surfaces of the channel layers 808. The source/drain regions 802 may be formed from a semiconductor material that is doped, for example including a p-type or n-type dopant, which may be formed in situ during the growth process or which may be implanted by an ion beam process. An interlayer dielectric 804 is deposited and is polished down to the height of the dummy gates 702 using, for example, a chemical mechanical planarization (CMP) process.

CMP is performed using, e.g., a chemical or granular slurry and mechanical force to gradually remove upper layers of the device. The slurry may be formulated to be unable to dissolve, for example, the work function metal layer material, resulting in the CMP process's inability to proceed any farther than that layer.

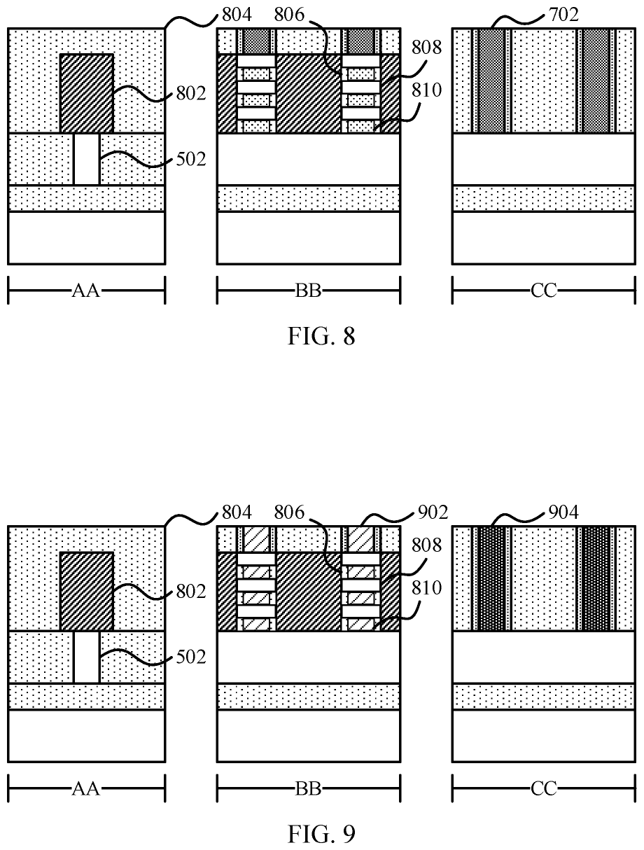

Referring now to FIG. 9, a series of cross-sectional views of a step in the fabrication of a semiconductor device is shown, including cross-sections AA, BB, and CC. A gate cut is performed by etching away the dummy gate 702 in a region between devices (e.g., as shown in cross-section CC) and filling the resulting gap with a dielectric gate cut structure 904. The remaining dummy gate material is then etched away and is replaced with a gate stack 902. The gate stack may include, e.g., a gate dielectric layer and a gate conductor.

The gate dielectric layer may be formed from a high-k dielectric material, having a dielectric constant k that is higher than that of silicon dioxide. Examples of high-k dielectric materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum.

The gate conductor may be formed from any appropriate conductive metal such as, e.g., tungsten, nickel, titanium, molybdenum, tantalum, copper, platinum, silver, gold, ruthenium, iridium, rhenium, rhodium, cobalt, and alloys thereof. The gate conductor may alternatively be formed from a doped semiconductor material such as, e.g., doped polysilicon.

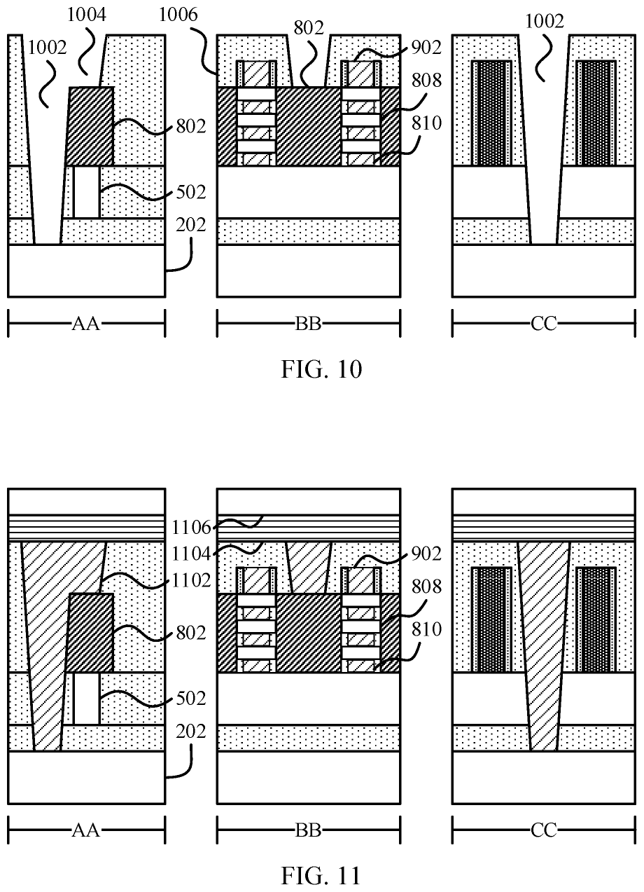

Referring now to FIG. 10, a series of cross-sectional views of a step in the fabrication of a semiconductor device is shown, including cross-sections AA, BB, and CC. Additional dielectric material is deposited to extend interlayer dielectric 1006 using any appropriate deposition process. Contact vias are etched through the interlayer dielectric 1006, including source/drain contact vias 1004 and buried power rail contact vias 1002. As shown in cross-section AA, the buried power rail contact via 1002 may overlap with the source/drain contact via 1004, and may furthermore partially cut through the source/drain structure 802 itself. The buried power rail contact via 1002 extends down through the buried oxide layer 204 to expose a surface of the buried semiconductor substrate 202.

Referring now to FIG. 11, a series of cross-sectional views of a step in the fabrication of a semiconductor device is shown, including cross-sections AA, BB, and CC. The source/drain contact vias 1004 and the buried power rail via 1002 are filed with a conductive material using any appropriate deposition process, producing contacts 1102. As shown in cross-section AA, the contacts 1102 may make substantial contact with the source/drain structures 802, but remain insulated from the thinned base substrate 502, preventing shorts between the contacts 1102 and the thinned base substrate 502.

Over top of the contacts 1102 and the interlayer dielectric 1006, back-end-of-line layers 1104 may be formed using any appropriate process. The back-end-of-line layers 1104 may include one or more layers of conductive lines that distribute signal information between devices, making electrical contact with the contacts 1102 of devices as needed. A carrier wafer 1106 may be positioned on the back-end-of-line layers 1104 to make maneuvering the chip easier. For example, the carrier wafer 1106 may be attached using a removable adhesive.

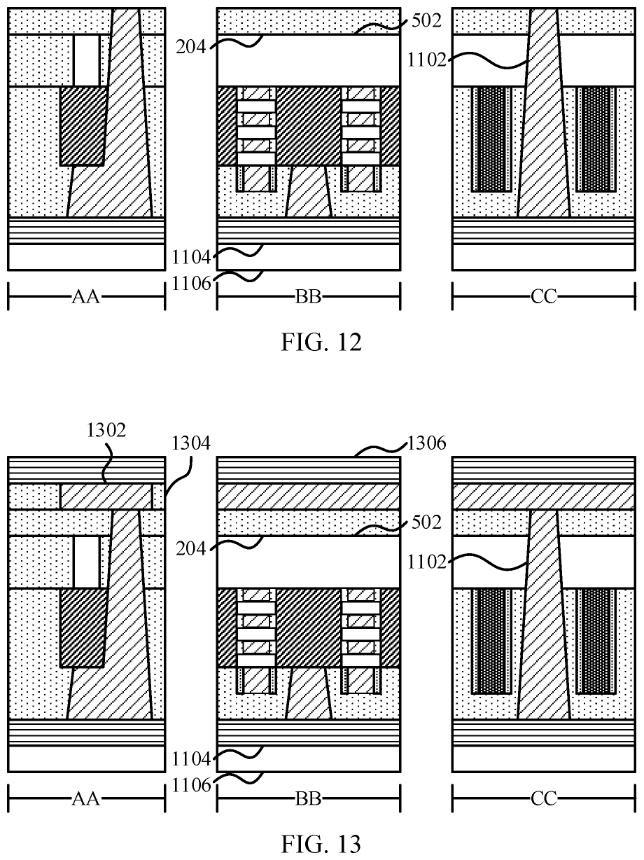

Referring now to FIG. 12, a series of cross-sectional views of a step in the fabrication of a semiconductor device is shown, including cross-sections AA, BB, and CC. The chip is flipped over and the bulk semiconductor substrate 202 is removed, exposing the buried oxide layer 204 and a surface of the contact 1102.

Referring now to FIG. 13, a series of cross-sectional views of a step in the fabrication of a semiconductor device is shown, including cross-sections AA, BB, and CC. A buried power rail 1302 is formed on the backside of the chip, in electrical contact with the contact 1102. A backside interlayer dielectric 1304 may be formed around the buried power rail 1302 by depositing a dielectric material (e.g., silicon dioxide) and polishing down to the level of the buried power rail 1302 using a CMP process. A buried power distribution network 1306 is formed on buried power rail 1302.

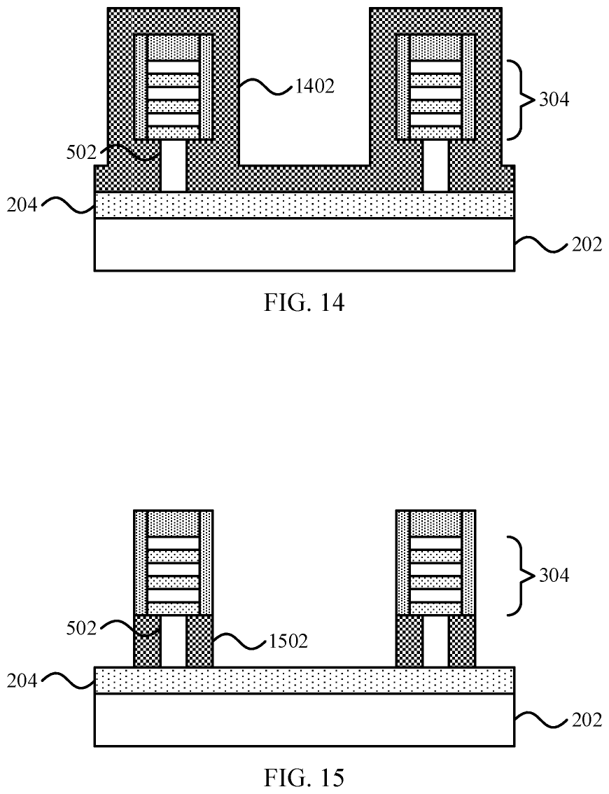

Alternative embodiments are also described herein, which illustrate different ways to insulate the base substrate from the buried power rail contact. One such alternative embodiment is shown that deposits an additional dielectric material around the thinned base substrate 502. This embodiment is described with respect to FIGS. 14-15. In the procedure described above, these alternative steps may be performed after the thinning of the substrate to form the thinned base substrates 502 and before the deposition of isolation dielectric 602.

Referring now to FIG. 14, a cross-sectional view of a step in the fabrication of an alternative embodiment of a semiconductor device is shown along cross-section AA. A layer of dielectric material 1402 is conformally deposited over the stacks 304 and on sidewalls of the thinned base substrates 502. The dielectric may be formed from any appropriate material that is selectively etchable with respect to the masks 306 and the protective layer 404. For example, the dielectric material may be selected to be a low-k dielectric material, to reduce capacitive coupling between the thinned base substrate 502 and the buried power rail contacts 1102.

Referring now to FIG. 15, a cross-sectional view of a step in the fabrication of an alternative embodiment of a semiconductor device is shown along cross-section AA. A selective anisotropic etch is used to remove exposed portions of dielectric material 1402, leaving dielectric spacers 1502. From this point, isolation dielectric 602 may be deposited and the remainder of the steps shown in FIGS. 6-13 may be performed as described above. A dielectric spacer 1502 will be positioned between the thinned base substrate 502 and the buried power rail contact 1102.

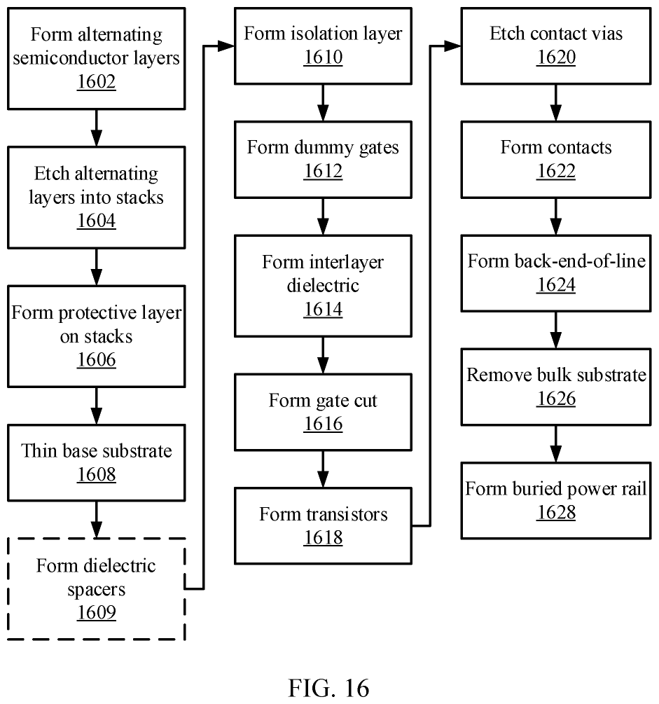

Referring now to FIG. 16, a method of forming contacts to a buried power rail is shown that includes thinning a base substrate of a transistor device. Block 1602 forms alternating sacrificial semiconductor layers 208 and channel semiconductor layers 210 on a substrate layer 206. Block 1604 etches the alternating layers into stacks 304 with corresponding base substrates 302.

Block 1606 forms a protective layer 404 on sidewalls of the stacks 304, for example by conformally depositing a dielectric material and then selectively and anisotropically etching the dielectric material from horizontal surfaces. The protective layer 404 may be kept off the base substrates 302 by forming a sacrificial layer 402, for example using an organic planarizing layer, that covers the sidewalls of the base substrates 302. The sacrificial layer 402 may then be removed.

Block 1608 thins the base substrates 302 to form thinned base substrates 502, for example using a timed, selective isotropic etch. At block 1609, dielectric spacers 1502 may optionally be formed on sidewalls of the thinned base substrates, for example by conformally depositing an appropriate dielectric material and then selectively and anisotropically etching away portions of the dielectric material that are exposed. Block 1610 forms a dielectric isolation layer 602 around the thinned base substrates 502 (and optional dielectric spacers 1502).

Block 1612 forms dummy gates 702 across the stacks 304, for example by patterning a layer of polysilicon using a photolithographic process and a selective anisotropic etch. Block 1614 forms an interlayer dielectric 804 around the dummy gates 702. Block 1616 forms a gate cut by removing a portion of the dummy gate 702 in a region between devices and replaces it with a dielectric structure 904. Block 1618 forms transistors, for example by forming inner spacers 806 and replacing the sacrificial layers with a gate stack 810.

Block 1620 etches vias 1002/1004 into an interlayer dielectric 1006, exposing a source/drain regions 802 of the transistor device and piercing down to the underlying bulk substrate layer 202. Block 1622 forms contacts 1102 in the vias 1002/1004 by depositing a material and polishing down to the level of the interlayer dielectric 1006. Block 1624 forms back-end-of-line layers 1104.

At this point, a handling wafer 1106 may be attached and the chip may be flipped over, exposing the bulk substrate layer 202. Block 1626 removes the bulk substrate layer to expose the buried oxide layer 204 and the contact 1102. Block 1628 then forms a buried power rail 1302 in electrical contact with the contact 1102. Backside power distribution network layers 1306 may additionally be formed over the buried power rail 1302.

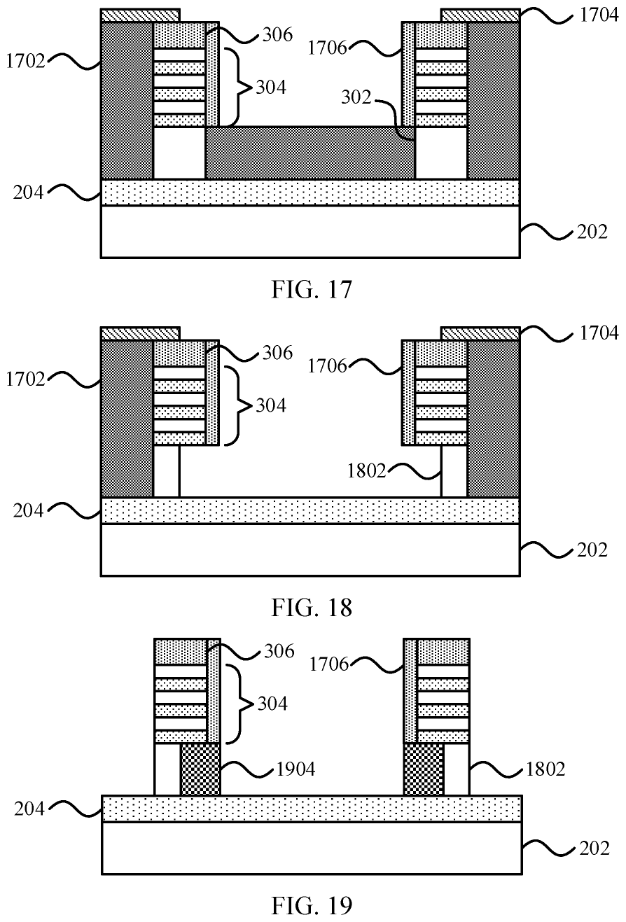

In other embodiments, rather than uniformly thinning the base substrates 206, the base substrates 206 may be etched back on a single side. This embodiment is described with respect to FIGS. 17-19. In the procedure described above, these alternative steps may be performed after the stacks 304 and 302 are formed and before the deposition of isolation dielectric 602.

Referring now to FIG. 17, a cross-sectional view of a step in the fabrication of an alternative embodiment of a semiconductor device is shown along cross-section AA. A sacrificial layer 1702 is formed, for example by depositing an organic planarizing material and etching the organic planarizing material back on one side of the stacks 304. An antireflective coating 1704, for example formed from a silicon-containing antireflective material, may be formed before etching back the organic planarizing material.

The sacrificial layer 1702 may therefore have a first height on a first side of a stack 304, and a second, lower height on a second side of the stack 304. For example, the sacrificial layer 1702 may have a same height as a mask 306 on the first side, and may have a same height as the base substrate 302 on the second side. The second height leaves a sidewall of the stack 304 exposed.

A protective layer 1706 may be formed on the exposed sidewall of the stack 304. The protective layer 1706 may be formed by a dielectric material that is conformally deposited and is then anisotropically etched away from horizontal surfaces.

Referring now to FIG. 18, a cross-sectional view of a step in the fabrication of an alternative embodiment of a semiconductor device is shown along cross-section AA. The portion of the sacrificial layer 1702 at the second height is etched away, exposing a sidewall of the base substrate 302. The base substrate 302 is then selectively etched, using a timed etch that removes material from the exposed surface. The resulting thinned base substrate 1802 is positioned on one side of the stack 304, farther away from the position of the eventual contact 1102. This positioning provides additional insulation between the tinned base substrate 1802 and the contact 1102.

Referring now to FIG. 19, a cross-sectional view of a step in the fabrication of an alternative embodiment of a semiconductor device is shown along cross-section AA. In an optional step, the gap left by thinning the base substrate may be filled by a dielectric, for example in the manner described above with respect to FIGS. 14 and 15. The resulting dielectric spacer 1902 further insulates the thinned base substrate 1802 from the buried power rail contact 1102, and may be formed from a low-k dielectric material to reduce capacitive coupling. From this point, isolation dielectric 602 may be deposited and the remainder of the steps shown in FIGS. 6-13 may be performed as described above. A dielectric spacer 1902 will be positioned between the thinned base substrate 502 and the buried power rail contact 1102.

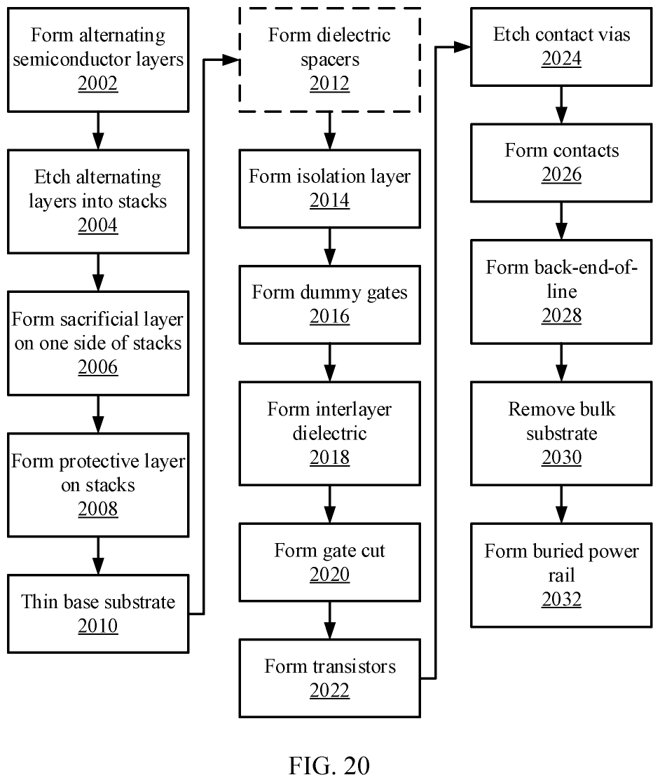

Referring now to FIG. 20, a method of forming contacts to a buried power rail is shown that includes thinning a base substrate of a transistor device. Block 2002 forms alternating sacrificial semiconductor layers 208 and channel semiconductor layers 210 on a substrate layer 206. Block 2004 etches the alternating layers into stacks 304 with corresponding base substrates 302.

Block 2006 forms a sacrificial layer 1702, such as an organic planarizing layer, that covers one side of each stack. Block 2008 forms a protective layer 1706 on sidewalls of the stacks 304, for example by conformally depositing a dielectric material on the exposed surfaces and then selectively and anisotropically etching the dielectric material from horizontal surfaces. The sacrificial layer 1702 may further block the formation of the protective layer 1706 from the base substrates 302. The sacrificial layer 1702 may then be removed.

Block 2010 thins the base substrates 302 to form thinned base substrates 1802, for example using a timed, selective isotropic etch. At block 2012, dielectric spacers 1902 may optionally be formed on sidewalls of the thinned base substrates, for example by conformally depositing an appropriate dielectric material and then selectively and anisotropically etching away portions of the dielectric material that are exposed. Block 2014 forms a dielectric isolation layer 602 around the thinned base substrates 502 (and optional dielectric spacers 1502).

Block 2016 forms dummy gates 702 across the stacks 304, for example by patterning a layer of polysilicon using a photolithographic process and a selective anisotropic etch. Block 2018 forms an interlayer dielectric 804 around the dummy gates 702. Block 2020 forms a gate cut by removing a portion of the dummy gate 702 in a region between devices and replaces it with a dielectric structure 904. Block 2022 forms transistors, for example by forming inner spacers 806 and replacing the sacrificial layers with a gate stack 810.

Block 2024 etches vias 1002/1004 into an interlayer dielectric 1006, exposing a source/drain regions 802 of the transistor device and piercing down to the underlying bulk substrate layer 202. Block 2026 forms contacts 1102 in the vias 1002/1004 by depositing a material and polishing down to the level of the interlayer dielectric 1006. Block 2028 forms back-end-of-line layers 1104.

At this point, a handling wafer 1106 may be attached and the chip may be flipped over, exposing the bulk substrate layer 202. Block 2030 removes the bulk substrate layer to expose the buried oxide layer 204 and the contact 1102. Block 2032 then forms a buried power rail 1302 in electrical contact with the contact 1102. Backside power distribution network layers 1306 may additionally be formed over the buried power rail 1302.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “an” and “the” are intended to include the plural forms as well, unless the context clearly indicates otherwise. It will be further understood that the terms “comprises,” “comprising,” “includes” a d/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of FET substrate trimming (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a semiconductor base having a first width;
a semiconductor device over the semiconductor base, having a second width that is greater than the first width;
a power rail beneath the semiconductor base; and
a conductive contact that extends from a top of the semiconductor device to the power rail.

2. The semiconductor device of claim 1, further comprising a interlayer dielectric, around the semiconductor base and the semiconductor device, that includes a portion of interlayer dielectric between the semiconductor base and the conductive contact.

3. The semiconductor device of claim 1, further comprising:
an interlayer dielectric around the semiconductor device and the semiconductor base; and
a dielectric spacer between the semiconductor base and the conductive contact, the dielectric spacer comprising a different material from the interlayer dielectric.

4. The semiconductor device of claim 1, wherein the semiconductor base has a sidewall that is vertically aligned with a sidewall of the semiconductor device.

5. The semiconductor device of claim 1, wherein the semiconductor device overhangs two sidewalls of the semiconductor base.

6. The semiconductor device of claim 1, wherein the conductive contact makes electrical contact with a sidewall of the semiconductor device.

7. The semiconductor device of claim 6, wherein the conductive contact makes direct electrical contact with a source/drain structure of the semiconductor device.

8. A semiconductor device, comprising:
a pair of adjacent semiconductor bases, each having a first width;
a pair of adjacent semiconductor devices, each positioned over a respective base of the pair of adjacent semiconductor bases and each having a second width that is greater than the first width, wherein the pair of adjacent semiconductor devices each have a sidewall that is vertically aligned with a sidewall of the respective base;
a power rail beneath the pair of adject semiconductor bases; and
a conductive contact that extends from a top of one of the pair of adjacent semiconductor devices to the power rail.

9. The semiconductor device of claim 8, wherein the conductive contact is between the semiconductor devices.

10. The semiconductor device of claim 8, wherein the aligned sidewalls of the respective semiconductor bases are on opposite sides of the respective semiconductor devices.

11. The semiconductor device of claim 8, further comprising a interlayer dielectric, around the semiconductor base and the semiconductor device, that includes a portion of interlayer dielectric between the semiconductor base and the conductive contact.

12. The semiconductor device of claim 8, further comprising:
an interlayer dielectric around the semiconductor device and the semiconductor base; and
a dielectric spacer between the semiconductor base and the conductive contact, the dielectric spacer comprising a different material from the interlayer dielectric.

13. A method of forming a semiconductor device, comprising:
etching a stack of alternating semiconductor layers over a semiconductor base;
forming a protective layer on a sidewall of the stack;
etching back a sidewall of the semiconductor base to reduce a width of the semiconductor base relative to a width of the stack;
forming a device from the stack; and
forming a contact that penetrates from above the device to below the semiconductor base.

14. The method of claim 13, wherein forming the protective layer includes depositing a protective material on two sidewalls of the stack.

15. The method of claim 13, wherein etching back the sidewall of the semiconductor base includes an isotropic etch that etches back two sidewalls of the semiconductor base.

16. The method of claim 13, further comprising etching a via, prior to forming the contact, that passes through a portion of a source/drain structure of the device.

17. The method of claim 13, further comprising forming a power rail in electrical contact with the contact.

18. The method of claim 13, further comprising depositing a dielectric spacer in a gap left by etching back the sidewall of the semiconductor base.

19. The method of claim 18, further comprising depositing an interlayer dielectric, after forming the device, from a different material from the dielectric spacer.

20. The method of claim 1, further comprising:
depositing a sacrificial material to a height of the semiconductor base, before forming the protective layer; and
removing the sacrificial material after forming the protective layer.
